(19) United States
(12) Patent Application Publication
(10) Pub. No.: US 2009/0289728 A1
(43) Pub. Date: Nov. 26, 2009

(54) Atomic frequency standard based on phase detection

(75) Inventors: Ido Ben-Aroya, Haifa (IL); Gad Eisenstein, Haifa (IL); Avinoam Stern, Jerusalem (IL); Michael Rosenbluh, Halamish (IL); Benny Levy, Maale Edomim (IL)

Correspondence Address: AVINOAM STERN, ACCUBEAT LTD., 5 HA'MARPE STREET, P.O.BOX 45102. HAR-HOZVIM, JERUSALEM, 91450, IL

(73) Assignees: AccuBeat Ltd.; Bar Ilan University; The Technion Research & Development Foundation Ltd

(21) Appl. No.: 12/153,731

(22) Filed: May 23, 2008

(51) Int. Cl. H03L 7/26

(52) U.S. Cl. 331/94.1

(57) ABSTRACT

This invention concerns the realization of a Coherent-Population-Trapping (CPT) atomic frequency standard by utilization of both the phase delay and the absorption of the light transmitted through an atomic vapor. The invented method enables the use of high modulation frequency and a fast lock of a low quality oscillator to the atomic hyperfine transition.

### FIELD OF THE INVENTION

The present invention relates generally to the field of atomic frequency standards. In particular it relates to vapor cell atomic frequency standards in which the phenomenon of coherent population trapping is used.

### DESCRIPTION OF PRIOR ART

There are two types of vapor cell frequency standards: an older one which is based on the phenomenon of Intensity Optical Pumping (IOP) and a newer one which is based on the phenomenon of Coherent-Population-Trapping (CPT).

IOP Frequency Standards

A comprehensive theory and description of most types atomic frequency standards may be found in: J. Vanier and C. Audoin, “The Quantum Physics of Atomic Frequency Standards”. In particular, a description of Intensity Optically Pumped (IOP) Frequency Standards is found in chapter 7: Rubidium Frequency Standards. Here we provide a short review only.

Most atomic frequency standards use alkali metal atoms where the hyperfine transition from F=1, m.sub.F=0 to F=2, m.sub.F=0 in the S.sub.1/2 ground state is used. For a rubidium it corresponds to a frequency of ˜6.835 GHz. In the context of atomic clock it is also called the “Clock Transition”. For a rubidium optical transitions from upper P.sub.1/2 and P.sub.3/2 levels to the ground state correspond to wavelengths of 780 nm (D2) and 794 nm (D1). See FIG. 1 for the energy levels diagram of a rubidium atom.

IOP Frequency Standards use a vapor cell, usually with rubidium atoms, and optical pumping to prepare the atomic ensemble into a special state that allows the detection of the resonance signal. This resonance is used to lock a crystal oscillator to the hyperfine transition of the atom. The principles of operation of an IOP rubidium frequency standard is described as follows: a state selection is performed by exposing a “resonance” cell with rubidium 87 atoms to a filtered radiation of a rubidium 87 spectral lamp. The filtering is done by another cell containing rubidium 85. This absorbs radiation corresponding to the transition from the ground level F=2 to the excited P state, thereby leaving a spectrum containing radiation which is resonant with the transition from the ground level F=1 to the excited P state. This filtering takes place for both radiation wavelengths D1 and D2. The net effect is to populate the ground hyperfine level F=2 at the expense of the F=1 level (population inversion). The resonance cell is placed in a microwave cavity resonating at a frequency around 6.853 GHz. This frequency is derived from a crystal oscillator. When it is tuned to the clock transition, stimulated emission occurres on the clock transition and the population of the F=1 level increases, thereby resulting in an increased absorption of the resonance cell detected by a photo-detector. The ground state hyperfine resonance signal is thus detected on the transmitted light and is used to lock the frequency of the crystal oscillator. The output of the system is derived from the crystal oscillator, which provides the short-term-stability, whereas the atoms provide the long-term-stability.

A possible approach uses a Frequency Lock Loop as shown in FIG. 2. A Crystal Oscillator (1) generates 10 MHz output to a Synthesizer that synthesizes the clock transition at 6.8 GHz. Microwave field at this frequency is used to change the transmission property of an alkali atomic cell (3). A detector/Integrator (4) is than used to lock the Crystal Oscillator (1) to the clock transition. The above scheme relies only on the population inversion and on the intensity of the absorption and not on its coherence, even in the case where a laser is used to accomplish the optical pumping.

CPT Frequency Standards

In recent years a new approach for frequency standards has been proposed. This method uses the phenomenon of Coherent Population Trapping (CPT) to prepare the atoms into a coherent superposition of energy states. No intensity optical pumping is used and the ensemble ground state populations are not altered by the phenomenon. A review of CPT frequency standard is found in J. Vanier, “Atomic clocks based on coherent population trapping: a review”, Appl. Phys. B 81, 441-442, 2005. A relevant patent is U.S. Pat. No. 6,320,472.

The principles of the CPT phenomenon are described by FIG. 3 in the so called “Lambda system”. The atoms are exposed to two coherent radiation fields corresponding to angular frequencies omega.sub.1 and omega.sub.2. The difference between omega.sub.1 and omega.sub.2 corresponds to the ground state angular hyperfine splitting frequency (clock frequency). The two radiation fields can be produced by two lasers locked to each other, or by the sidebands of a single laser that is modulated at a sub-harmonic of the alkali atom hyperfine frequency. The effect of the two radiation fields is to produce a strong coherence in the ground states at the hyperfine frequency and to trap all atoms in a superposition of the two ground states (F1 and F2), hence the name “Coherent Population Trapping”.

As the difference omega.sub.1 minus omega.sub.2 is scanned, the following phenomena occur as the difference passes through the hyperfine clock transition frequency: (1) a sharp increase in the transparency (decrease of absorption) of the atoms, (2) a sharp decrease of fluorescence (relating to the transition D1 or D2).

This resonance effect reflects all the properties of the ground state hyperfine resonance as observed in the intensity optical pumping approach.

The CPT approach is currently under research. A possible CPT method for implementing a frequency standard is illustrated in FIG. 4. The scheme here is that of Frequency Lock Loop (FLL). A crystal oscillator (5) followed by a multiplier/synthesizer (6) produces a frequency at half of the hyperfine clock frequency. Concerning Rubidium, this frequency equals ˜3.42 GHz. The synthesizer frequency is phase modulated (PM) by a modulator (7) at a very low frequency (˜100 Hz to ˜1 kHz) and lower than the clock transition linewidth). The modulated 3.42 GHz is used to modulate the drive current of a VCSEL diode laser (9) operating at 795 nm (corresponding in this example to the rubidium D1 line) or at 780 nm (which corresponds to the D2 transition) and to produce two sidebands which are spectrally separated by 6.84 GHz. The resulting linearly polarized beam of radiation is passed through a quarter wave plate which acts as a circular polarizer (10). The circularly polarized light passes through a rubidium vapor cell (11). In order to determine whether the modulation frequency (at ˜3.42 GHz) is correct, one uses either the transparency of the vapor, or the decrease in fluorescence. The signal from the photo-diode is demodulated by a demodulator (13) so that the output is proportional to the derivative (first difference) of the absorption line, and this is used to lock the crystal oscillator (1) to the hyperfine frequency. Additional servo-loops are required in order to stabilize the laser frequency and the intensity of the two AM side modes.

A modification of the scheme shown in FIG. 4 avoids the low frequency crystal oscillator. In this case, a tunable RF generator is used which is fed by, and locked through, the output of the demodulator. The output signal in this case is at the RF frequency −3.4 GHz.

A key advantage of the CPT method is that it offers operation without a microwave cavity, which is required in the IOP case, thus enabling a substantial size reduction.

### SUMMARY OF THE INVENTION

This invention concerns the realization of a Coherent-Population-Trapping (CPT) atomic frequency standard using the phase shift (or the dispersion) which can be combined with the absorption of the light transmitted through an atomic vapor. The following method is proposed:

As the frequency difference of the two optical fields used in the CPT is swept through the “clock transition”, one observes a sharp change in the intensity of the transmitted light, and the phase of each field exhibits a dispersive (derivative like) behavior. The present invention utilizes this phase change or a combination of phase and intensity changes to detect the transition and lock an RF oscillator to this clock transition frequency. These changes are detected by employing the Double-field FM spectroscopy method, namely: by modulating the frequency of the two optical fields which are required for CPT and demodulating the transmitted light. The resulting in-phase, out-of-phase (quadrature) or a combination of the two are chosen for optimum operation of the circuit that locks the RF generator. Furthermore, a specific method is suggested so that one can use a modulation frequency (f.sub.m) which is much larger than the width of the clock transition This facilitates a fast lock of the RF generator to the clock transition.

The medium in which CPT is used to determine the transition frequency could be an atomic vapor of Rubidium, Cesium, Potassium, Sodium or any other element in which CPT phenomena can be observed or it could be a solid or soft material in which CPT can be observed.

### DETAILED DESCRIPTION OF THE INVENTION

This invention is about the realization of a Coherent-Population-Trapping (CPT) Atomic Frequency Standard using the phase shift (or the dispersion) combined with the intensity change experienced by the light transmitted through the atomic vapor.

A new scheme to materialize the Atomic Frequency Standard is shown in FIG. 5:

The configuration is similar to the one described in FIG. 4; However, the new blocks (18) (Demodulator for Phase and Absorption Detection) and (23) (Low-Medium Frequency Generator), replace blocks (8) and (13) in FIG. 5.

The differences between the new scheme (FIG. 5) and the old one (FIG. 4) are:
The demodulation is performed in such a way so as to detect both the dispersion (phase-shift) and absorption the two electromagnetic fields experience while interacting with the medium (instead of absorption changes only).
The modulation frequency is not limited to values smaller than the width of the CPT resonance. For example, a modulation frequency of 10 kHz could be applied for resonance width of 1 kHz.

As described above, when the frequency difference (omega.sub.2 minus omega.sub.1) of the two electromagnetic fields used for the CPT process are swept through the “clock transition”, one observes a sharp dip in the absorption of the two fields. Simultaneously, as can be seen from the Kramers-Kronig relations each optical field experiences a phase-shift with a dispersion-like behavior (whose spectrum resembles the derivative of the dip in the absorption spectrum). However the dispersion each one of the fields experiences is different.

In order to detect the phase shift, we apply the following method:

The output frequency of the RF generator (blocks (15) and (16) in FIG. 5) is written as omega.sub.mu. We phase modulate (PM) this output at a low-medium frequency (omega.sub.m) using the modulator (17). In the prior-art omega-sub-m was limited to frequencies below the CPT resonance width. Here, omega-sub-m is not restricted and could be much larger than the CPT resonance width. A typical resonance width for a rubidium vapor is a few hundred hertz. In our case we can use much higher modulation frequency in the kHz or even in the MHz ranges. This has an advantage over the current method as explained below. Than the RF generator (16a) output is applied to modulate the laser drive current (19), resulting in an emitted optical spectrum which contains groups of high and low sidebands. The first six sidebands are shown schematically in FIG. 6.

The laser light is than transmitted through a circular polarizer (20) and through an atomic vapor cell (21). Resonance is obtained whenever the difference in frequency between any two spectral lines matches the CPT resonance (the “clock transition”), i.e., whenever the clock transition frequency equals twice omega.sub.mu plus an integer times omega.sub.m. For example, the clock frequency could be equal to the frequency difference between line +2 to line −3 in FIG. 6. This means that we are not restricted to a modulation frequency below the resonance width.

Next, the transmitted light is detected by a photo-diode (22), followed by a demodulator (23). The demodulator demodulates the output of the photo-diode (22) at an (angular) frequency equal to the modulation (angular) frequency omega.sub.m. Both demodulated signals, namely the in-phase and out-of-phase (quadrature) signals contain a signature of the spectroscopic characteristics of the probed process/medium. The spectrum of one of the two signals crosses zero with a large slope which is used to stir and lock the Crystal Oscillator (15) and the RF Generator (16a) to the CPT resonance. See also remark 1 below.

Referring again to FIG. 6, a CPT resonance is obtained with any pair of lines whose frequency difference matches the clock transition. When the modulation frequency (omega.sub.m) falls within half the resonance width than the detected signal is actually derived form a superposition of several resonances, related to several pairs of lines. When the modulation frequency is larger than the resonance width, than the detected signal originates from a single pair of lines. One may use either a signal originating from absorption, phase delay or combination of both. It can be shown that the slope obtained using the phase shift detection is similar to the slope obtained using the absorption detection. However, operating at a modulation frequency (omega.sub.m) greater than the CPT resonance width necessitates the use of phase detection or a combination of phase and absorption detection. Operating at high modulation frequency enables the realization of a very fast frequency lock loop and allows for the use of simple, less stable RF oscillators. In this case, however, the modulation frequency omega.sub.m should better be synchronized to the RF Generator.

Remarks
1. The demodulation is implemented using lock-in techniques which yield two outputs. The relative phase between the signal and the reference can be varied so as to get an optimum feedback signal in the locking circuit for any low frequency modulation parameters. This means that the FM modulation frequency can be chosen at will and for each such frequency, one can choose a modulation index and a relative phase between the signal and the reference to the lock-in circuit that together yield the largest slope in the spectrum of the feedback signal together with the lowest accompanying noise. Choosing that reference phase amounts to fixing a particular combination of amplitude and phase modulation of the optical signal.
2. The RF generator can have two configurations. In one it may use a low frequency oscillator followed by a synthesizer that produces the required RF signal of 3.4 GHz. In this case, the demodulating circuit feeds the low frequency oscillator in the locking loop. This configuration enables two stabilized output signals, one at the low frequency of the oscillator and one at the RF frequency. The second configuration does not use a low frequency oscillator but rather a tunable RF generator at 3.4 GHz which is fed by the demodulating circuit in the locking loop. This configuration enables just one output signal at the RF frequency of 3.4 GHz.

### DESCRIPTION OF THE DRAWINGS

FIG. 1: Energy levels diagram of a Rubidium atom

FIG. 2: Frequency Lock Loop used in Vapor IOP Frequency Standard

FIG. 3: The Lamda system of the Rubidium D1 line

FIG. 4: Prior art scheme of CPT Clock

FIG. 5: New scheme for CPT Clock

FIG. 6: First six sidebands due to double modulation of the laser

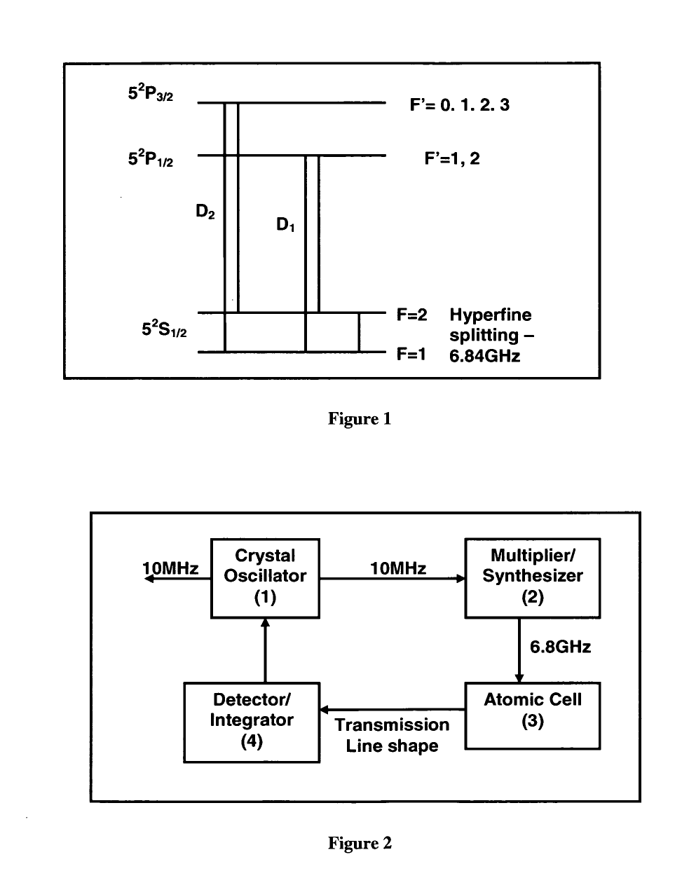

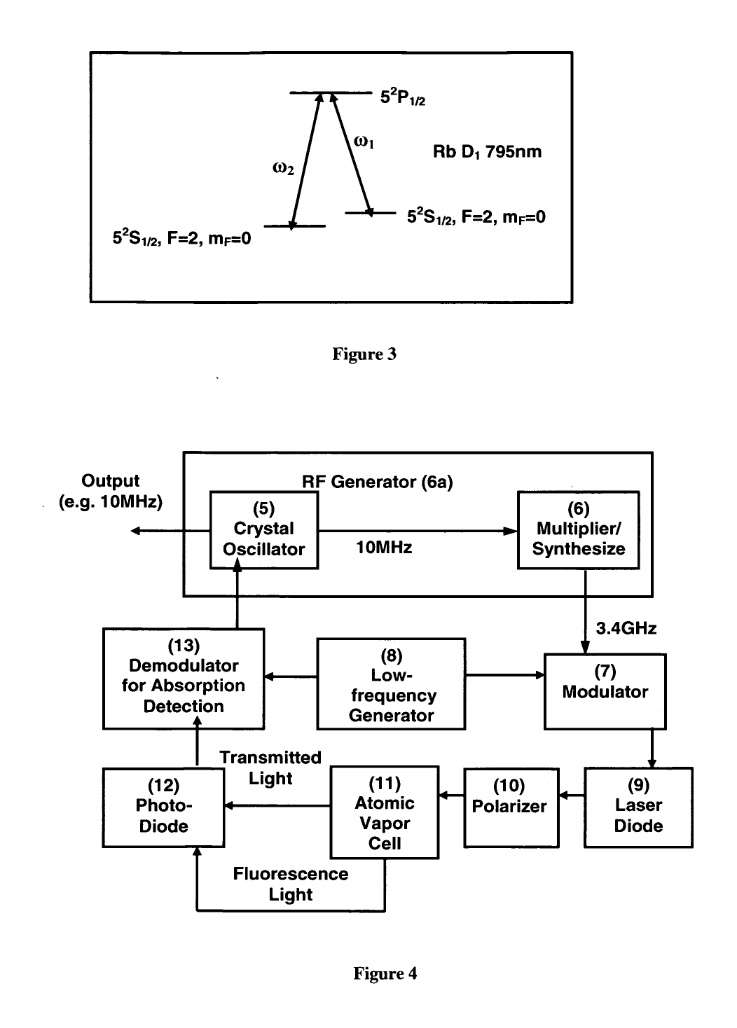

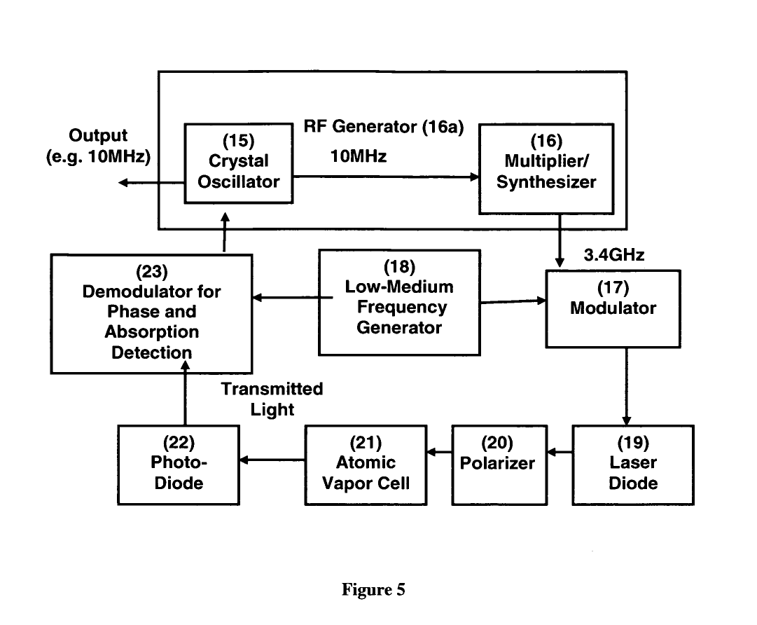

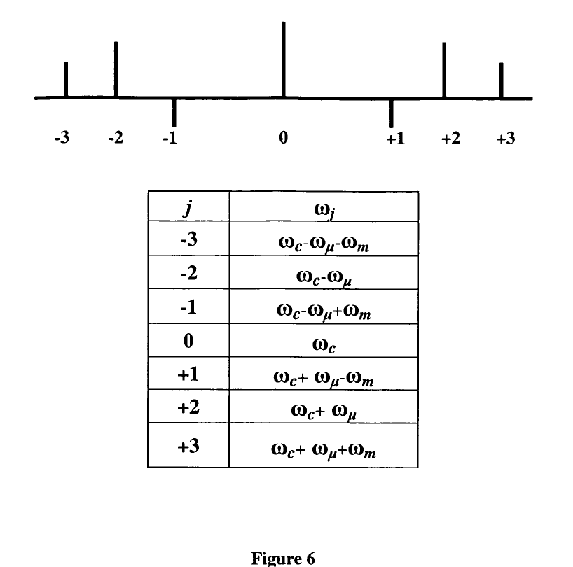

### REFERENCES CITES

U.S. Patent Documents: U.S. Pat. No. 6,320,472 November 2001 J. Vanier

Other Publications:

J. Vanier and C. Audoin, “The Quantum Physics of Atomic Frequency Standards” Institute of Physics Publishing, Bristol, UK, 1989.

J. Vanier, “Atomic clocks based on coherent population trapping: a review”, Appl. Phys. B 81, 441-442, 2005

What is claimed is:

1. An atomic frequency standard comprising:
a. A cell containing a mixture of alkali metal atoms and a mixture of buffer gases non reactive with said alkali metal atoms, said mixture being selected to minimize the temperature coefficient within said cell;
b. A laser whose emitted wavelength corresponds to either of the D1 or the D2 transition of the said alkali metal atoms.
c. A combination of optical components that set the state of polarization of the light to be circularly polarized.
d. An RF generator that generates a frequency whose value is the hyperfine ground state 0-0 transition frequency of said alkali metal atoms (the “clock transition”) divided by an integer number. The RF output is phase modulated (PM) or amplitude modulated (AM) at a low frequency (below 100 kHz).
e. The said generator output is used to amplitude modulate (AM) the current of the said laser. The laser emission is thus amplitude, frequency and phase modulated. The modulated RF drive current is modulated at a rate lower than the said RF frequency but could be much higher than the resonance width. As a result the laser light is AM and PM modulated containing AM sidebands each of which carries its own low frequency FM sidebands. The number of AM sidebands is controlled by the RF power level while the number of FM sided bands is controlled by the FM modulation index, namely the amplitude of the electrical FM modulation signal.
f. A photo-detector placed behind the vapor cell is used to detect the variations in the intensity of the light transmitted through said cell.
g. A circuit that demodulates the variations in the light intensity. The demodulation is performed in-phase or in quadrature to the said low frequency FM modulation, or in a mixture of both so that the demodulated signal is mostly related to a phase shift difference of the transmitted light.
h. A frequency control loop that uses the said phase shift difference signal to lock the RF generator to the zero crossing point of the phase difference. The said RF generator frequency is tuned so that the clock transition frequency corresponds to a difference in frequency between one of the high and one of the low side bands.

2. The standard of claim 1 where the RF generator comprises of an oscillator and a frequency multiplier and synthesizer that together produce an output at said RF frequency.

3. The standard of claim 1 wherein the said low frequency modulation is above 100 kHz.

4. The standard of claim 1 wherein the one laser is replaced by a pair of lasers, the frequencies of said lasers being separated by the hyperfine frequency of said alkali metal atoms and each laser is modulated at a low frequency.

5. The standard of claim 1 wherein said lasers are phase locked.

6. The standard of claim 1 wherein the said separation of frequencies is implemented by frequency locking of said lasers.

7. The standard of claim 1 wherein each said laser is a Vertical Cavity Surface Emitting Laser (VCSEL).

8. The standard of claim 1 wherein each said laser is a distributed feedback (DFB) laser

9. The standard of claim 1 wherein each said laser is a multi section distributed feedback (multi section DFB) laser where the phase control section is used for the PM modulation

10. The standard of claim 1 wherein each said laser is a distributed Bragg reflector (DBR) laser

11. The standard of claim 1 wherein each said laser is a multi section distributed Bragg reflector (DBR) laser (multi section DBR) laser where the phase control section is used for the PM modulation.

12. The standard of claim 1 wherein said alkali metal atoms are selected from the group consisting of cesium 133, rubidium 85 and rubidium 87.

13. The standard of claim 1 wherein an interior surface of said cell comprises an inert coating selected to prevent wall relaxation of alkali metal atoms contacting the said interior surface.

14. The standard of claim 13 wherein said inert coating is a long chain paraffin wax.

15. The standard of claim 1 wherein said light polarizer is a circular polarizer.

16. The standard of claim 1 comprising a combination of a linear polarizer and a circular polarizer.
